(19) United States
(12) Patent Application Publication
(10) Pub. No.: US 2006/0164809 A1
(43) Pub. Date: Jul. 27, 2006

(54) Heat dissipation module

(75) Inventors: Min-Hui Yu, Taoyuan Hsien (TW); Ming-Te Chuang, Taoyuan Hsien (TW); Chi-Feng Lin, Taoyuan Hsien (TW); Chin-Ming Chen, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/295,530

(22) Filed: Dec. 7, 2005

(30) Foreign Application Priority Data
Jan. 21, 2005 (TW) 94101757

(51) Int. Cl. H05K 7/20

(52) U.S. Cl. 361/704

(57) ABSTRACT

A heat dissipation module includes a first annular wall, a second annular wall, at least one porous structure, at least one first heat conductive structure and second heat conductive structure. The second annular wall with respect to the first annular wall, and the first annular wall and the second annular wall are jointed to form a closed chamber. The porous structure is disposed on an inner surface of the closed chamber. The first heat conductive structure is externally connected to the first annular wall and the second heat conductive structure is internally connected to the second annular wall.

This Non-provisional application claims priority under U.S.C. § 119(a) on Patent Application No(s). 094101757 filed in Taiwan, Republic of China on Jan. 21, 2005, the entire contents of which are hereby incorporated by reference.

### BACKGROUND

The invention relates to a heat dissipation module, and in particular to a high efficiency heat dissipation module.

When the number of transistors per unit area of an electronic device increases, the amount of heat generated also increases greatly during the electronic element's operation. Additionally, the high operating frequency of an electronic device and switch loss resulting from the switch shifting of the transistor are main causes for the increased amount of heat. The operating speed of the electronic device, such as a chip, will decrease if the heat is not properly dispersed, thus, affecting the lifespan of the chip. Typically, a heat sink is used to transfer the heat generated from a heat source to the heat sink and heat is dissipated out to an exterior environment through fins of the heat sink by means of natural or forced convection.

Some existing problems, however, may not be solved by a conventional heat sink. For example, the temperature difference between the air at a fin surface and the air at the heat sink is only 5-10 celsius degrees (° C.), resulting in insufficient temperature gradient. Moreover, since thermal resistance caused by restrained material and structure of the heat sink, the conventional heat sink provides only 70% or less heat dissipation efficiency and provides low heat dissipation capacity.

A heat pipe can transfer heat over a long distance within a small cross section and under minor temperature differences. The heat pipe can be operated in the absence of power and is thus widely used to remove heat generated by an electronic device. Therefore, various heat pipes are used to transfer heat in electronic heat dissipation products.

Referring to FIG. 1A, FIG. 1A is a schematic view of a conventional heat dissipation module 100a. The conventional heat dissipation module 100a is composed of a heat column 110 and heat dissipation fins 130. The heat column 110 has a capillary structure at its inner surface. The heat dissipation module 100a mainly conducts heat to the heat dissipation fins 130 from a heat source via the heat column 110, and then dissipates heat by convection.

Referring to FIG. 1B, FIG. 1B is a schematic view of another conventional heat dissipation module 100b. The conventional heat dissipation module 100b is composed of a heat plate 120 and heat dissipation fins 140. The heat plate 120 has a capillary structure at its inner surface. The heat dissipation module 100b mainly conducts heat to the heat dissipation fins 140 from a heat source via the heat column 120, and then dissipates heat by convection. Comparing the heat column 110 in FIG. 1A and the heat plate 120 in FIG. 1B, the heat plate 120 is more suitable for a heat source with larger area than the heat column 110 because the heat plate 120 has larger contact area than the heat column 110.

Considering the heat conduct area between the heat source, heat dissipation fins and the heat pipe/heat column limited to the size of the outside surface thereof, it is important to develop a new heat dissipation module with greater conduct area so as to achieve higher dissipation efficiency. Also, in view of increasing density of fabricated elements in various electronic products, causing heat to increase gradually, it is therefore an important subject of the present invention to provide an economical and flexible heat dissipation module with better conductive ability and smaller size.

### SUMMARY

To solve the described problems, the invention provides a heat dissipation module having an innovative closed chamber capable of not only dissipating heat rapidly but also having high dissipation efficiency.

Heat dissipation modules are provided. An exemplary embodiment of a heat dissipation module includes a first annular wall, a second annular wall, and a porous structure. The second annular wall is with respect to the first annular wall, and the first annular wall and the second annular wall are jointed to form a closed chamber. The porous structure is attached to an inner surface of the closed chamber.

The heat dissipation module further includes at lease one first heat conductive structure externally connected to the first annular wall. Alternatively, the heat dissipation module further includes at lease one second heat conductive structure internally connected to the second annular wall. The heat dissipation module is used cooperating with a fan to speed up the heat dissipation of the heat conductive structures. The first heat conductive structure or the second heat conductive structure can include several fins or heat conductive sheets. The individual fins or heat conductive sheets of the heat conductive structure are arranged by intervals horizontally, vertically, obliquely, radially, or arranged in other ways. The first heat conductive structure and the second heat conductive structure are respectively connected to the first annular wall and the second annular wall by means of soldering, locking, engaging, wedging, or gluing. Further, the heat dissipation module includes a soldering paste, a grease, or other applicable material capable of acting as a heat conductive interface between the first heat conductive structure and the first annular wall or between the second heat conductive structure and the second annular wall.

The shape of the first annular wall and the second annular wall is a circle, an ellipse, a semicircle, a rectangle, a triangle, a trapezoid, an equilateral polygon, or a scalene polygon. The closed chamber is disposed on a base, and the shape of the base corresponds to a heat source. The base has a heat absorbing portion to directly conduct heat from the heat source to the heat dissipation module. The first annular wall and the second annular wall are jointed to form the closed chamber by one-sided tube reduction (or expansion), two-sided tube reduction (or expansion), one-sided chute, or using a stopper. The closed chamber is sealed by soldering, plasma technology or high frequency welding technology. In addition, the sectional shape of the stopper is a circle, an ellipse, a semicircle, a rectangle, a triangle, a trapezoid, a regular polygon, or a scalene polygon.

### DESCRIPTION OF THE DRAWINGS

The invention can be more fully understood by reading the subsequent detailed description and examples with references made to the accompanying drawings, wherein:

FIG. 1A is a schematic view of a conventional heat dissipation module;

FIG. 1B is a schematic view of another conventional second heat dissipation module;

FIG. 2A is a schematic view of an embodiment of a heat dissipation module;

FIG. 2B is a schematic view showing the heat conductive direction of the heat dissipation module in FIG. 2A;

FIG. 2C is an exploded view of the heat dissipation module in FIG. 2A;

FIG. 2D and FIG. 2E are schematic views showing that a heat conductive structure and a closed chamber are combined by a self tapping screw;

FIG. 3A and FIG. 3B are schematic views of other embodiments of a closed chamber;

FIGS. 4A-4F are schematic views of the heat dissipation module in FIG. 2B, which shows that two annular walls are connected to each other in various ways; and

FIGS. 5A-5D are schematic views of the heat dissipation module in FIG. 2A, which shows that the conductive structures are disposed in various ways.

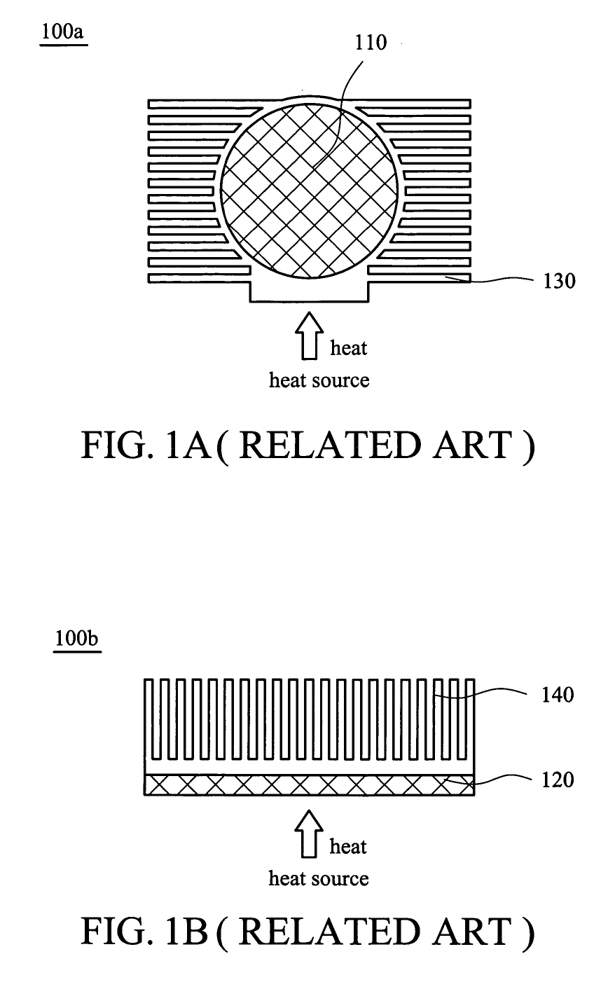

### DETAILED DESCRIPTION

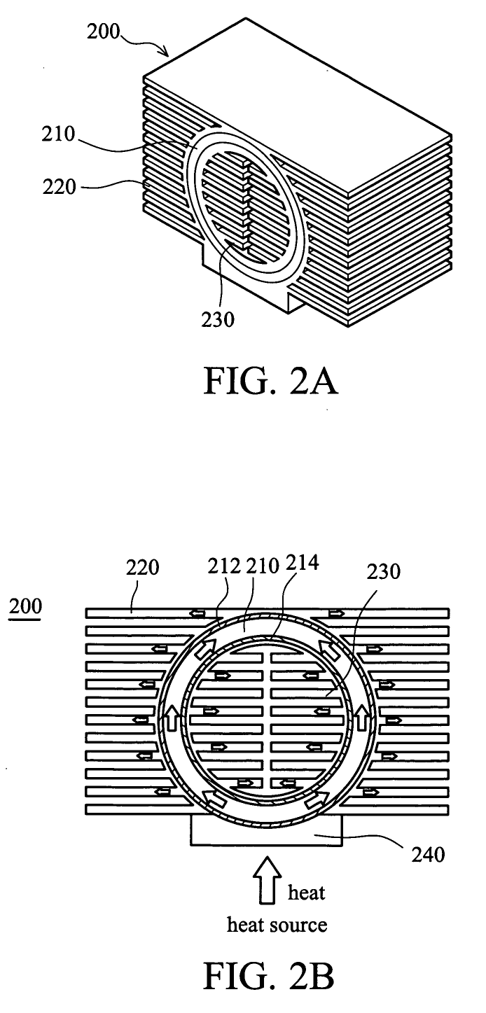

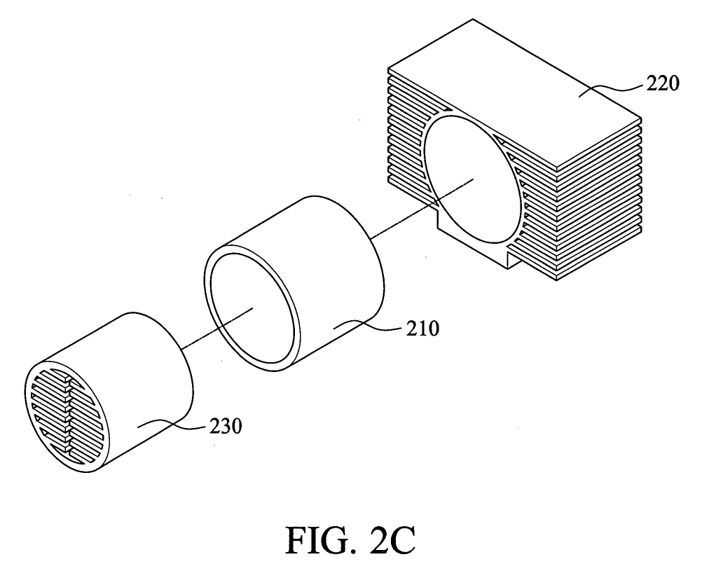

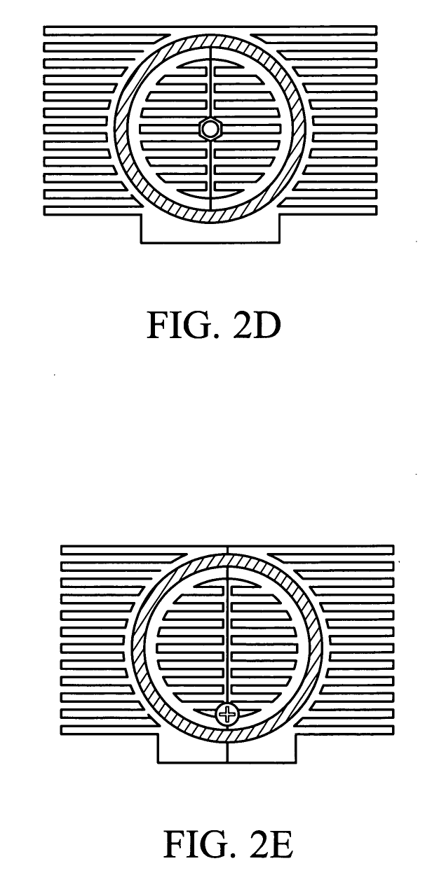

Referring to FIGS. 2A, 2B and 2C, FIG. 2A is a schematic view of an embodiment of a heat dissipation module 200. FIG. 2B is a schematic view showing the heat conductive direction in FIG. 2A, and FIG. 2C is an exploded view of the heat dissipation module 200 in FIG. 2A. The heat dissipation module 200 includes a closed chamber 210, a first heat conductive structure 220, and a second heat conductive structure 230. The second annular wall 214 is with respect to the first annular wall 212, and the first annular wall 212 and the second annular wall 214 are jointed to form the closed chamber 210. The first annular wall 212 and the second annular wall 214 are independent from each other, and correspondingly engaged. There is a porous structure disposed on the inner surface of the closed chamber 210. In other words, the first annular wall 212 and the second annular wall 214 have a porous structure respectively, and a vapor room is formed when the first annular wall 212 and the second annular wall 214 are jointed.

The first heat conductive structure 220 is externally connected to the first annular wall 212 of the closed chamber 210, and the second heat conductive structure 230 is internally connected to the second annular wall 214 of the closed chamber 210, so that the first heat conductive structure 220 and the second heat conductive structure 230 conduct heat absorbed by the closed chamber 210 out of the closed chamber 210. The closed chamber 210 contacts a heat source directly or via a base 240 and the closed chamber 210 further conducts heat to the heat dissipation module 200. The heat source is preferably a heat producing electronic element, such as a CPU, a transistor, a server, an accelerated graphics card, a hard disc, a power supply, a vehicle control system, a multimedia electronic device, a wireless station, or a game system (PS3, XBOX, Nintendo).

If adequate space is available, the closed chamber 210, the first heat conductive structure 220, and the second heat conductive structure 230 of the present invention can also cooperate with a fan, according to users' requirements. Alternatively, the heat dissipation module 200 is directly disposed in an air passage of a system. Thus, the heat dissipation of the first heat conductive structure 220 and the second heat conductive structure 230 may be speed up by an air flow of the fan or the system.

The base 240 is integrally formed with the first heat conductive structure 220, and uses the same material as the first heat conductive structure 220. Or, the base 240 can also be formed separately. As shown in FIG. 2B, the base 240 can be made by copper, metal, alloy, or other highly heat conductive material. The base 240 directly contacts the heat source, and includes a heat absorbing portion, which may directly conduct heat away from the heat source. Also, the shape of the base 240 flexibly varies depending on the corresponding heat source. The base 240 is suitable for a small-sized CPU or a large-sized power supply, thus, increasing the design flexibility of the heat dissipation module 200.

Conventional heat pipes, including the heat plate and the heat column, simply contact the heat source and the heat dissipation fin at one outer surface. Conversely, the closed chamber 210 of this embodiment has an internal surface(the first annular wall 212) and an external surface(the second annular wall 214) connected to the first heat conductive structure 220 and the second heat conductive structure 230 respectively. The heat generated from the heat source is transferred through both the internal surface (the first annular wall 212) and the external surface (the second annular wall 214) away from the heat source. Hence, the total heat dissipation area is twice as large as the conventional, thus providing the closed chamber 210 with high dissipation efficiency.

The first heat conductive structure 220 and the first annular wall 212 or the second heat conductive structure 230 and the second annular wall 214 are connected by means of soldering, locking, engaging, wedging, and gluing. Referring to FIG. 2C, when the first heat conductive structure 220 and the first annular wall 212 are connected by means of engaging or wedging, the internal diameter of the first heat conductive structure 220 is designed to be slightly smaller than the largest external diameter of the closed chamber 210, so that the closed chamber 210 and the first heat conductive structure 220 are tightly fit when the first heat conductive structure 220 and the closed chamber 210 are tightly fit by heat mounting according to the thermal expansion and contraction principle. Similarly, the internal diameter of the closed chamber 210 is designed to be slightly smaller than the largest external diameter of the second heat conductive structure 230 so that the closed chamber 210 and the second heat conductive structure 230 are tightly fit. Moreover, the second heat conductive structure 230 is fitted to the closed chamber 210 by a bolt, a slide, or a self tapping screw(as shown in FIG. 2D and FIG. 2E).

In order to improve conductive ability, the smoothness of the contact surface between the first heat conductive structure 220 and the first annular wall 212, or between the second heat conductive structure 230 and the second annular wall 214 must be increased. Thus, the heat dissipation module 200 further includes a soldering paste, grease, or other applicable material capable of acting as a heat conductive interface between the first heat conductive structure 220 and the first annular wall 212, or between the second heat conductive structure 230 and the second annular wall 214. Note that the number of the first heat conductive structures 220 or the second heat conductive structures 230 is not limited to one. For example, the first heat conductive structure 220 or the second heat conductive structure 230 may be formed by combining more than two heat conductive structures. That is, the first heat conductive structure 220 externally connected to the closed chamber 210 may be formed by combining more than two heat conductive structures. Similarly, the second heat conductive structure_230 internally connected to the second annular wall 214 may be formed by combining more than two heat conductive structures.

The porous structure is disposed on the inner surface of the closed chamber 210, and the porous structure can be made of plastic, metal (such as copper, aluminum and iron), or porous nonmetal material. For example, the porous structure may be a wick, including a mesh, fiber, sinter, and/or groove. The porous structure may be disposed on and attached to the closed chamber 210 by sintering, gluing, stuffing and/or depositing. Further, the porous structure is either formed both on the first annular wall 212 and the second annular wall 214, or only formed on the first annular wall 212 or the second annular wall 214.

A working fluid is contained in the porous structure, and the working fluid may be inorganic compounds, water, alcohol, liquid metal, ketone, CFCs, or other organic compounds. The boiling point of the working fluid is controlled by the pressure in the vapor room.

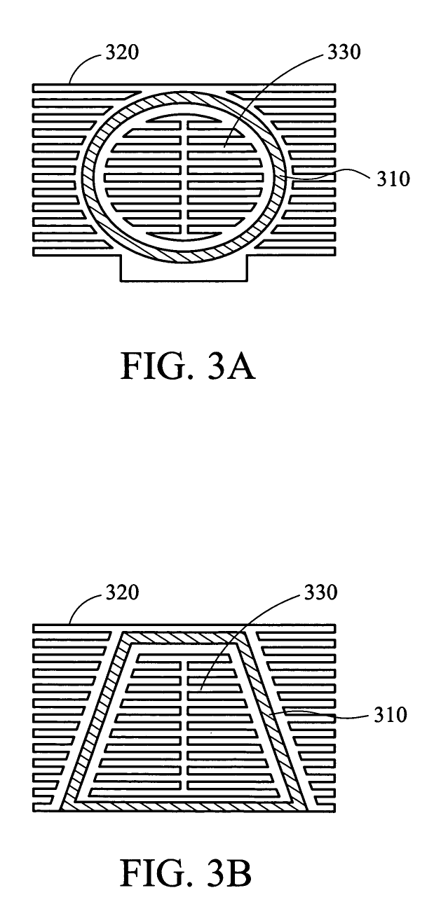

FIG. 3A and FIG. 3B are schematic views of other embodiments of the closed chamber. The shape of the closed chamber may be changed if necessary. For example, the closed chamber 210 in FIG. 2B has a round shape, but the shape of the closed chamber can be an ellipse (as shown in FIG. 3A), a semicircle, a rectangle, a triangle, a quadrangle, a trapezoid (as shown in FIG. 3B), an equilateral polygon, or a scalene polygon. Also, the shapes of the heat conductive structures 210, 320 are designed corresponding to the closed chamber 310 so as to achieve fine conductivity, as shown in FIGS. 3A and 3B.

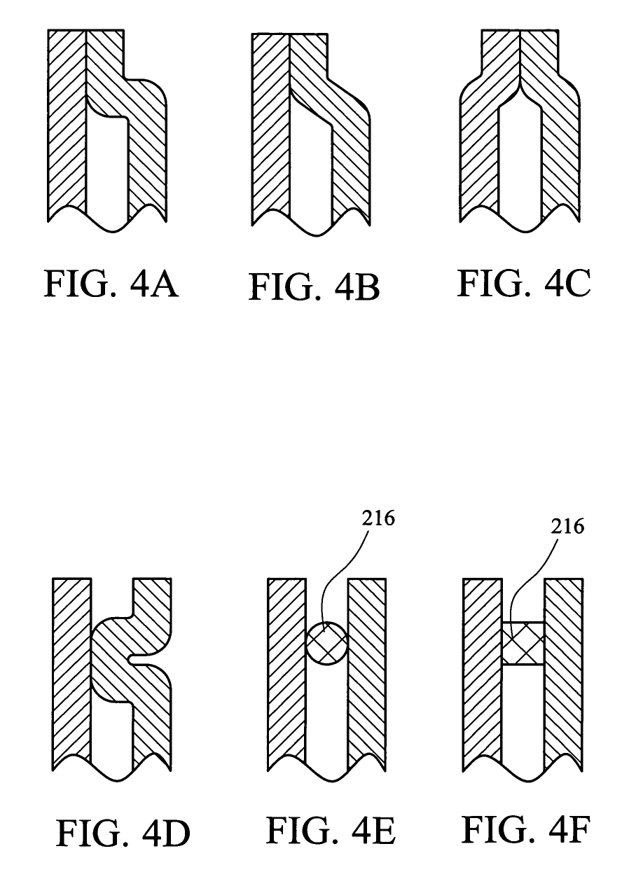

Additionally, the connection between the first annular wall 212 and the second annular wall 214 in FIG. 2A is not limited to particular one method, as long as the connection allows the first annular wall 212 and the second annular wall 214 to be jointed to form a closed chamber. Referring to FIG. 4A to FIG. 4F, which are schematic views of the heat dissipation module in FIG. 2B, showing that two annular walls 212, 214 are connected to each other in various ways. The first annular wall 212 and the second annular wall 214 are jointed to form the closed chamber 210 by one-sided tube reduction or expansion (as shown in FIG. 4A and FIG. 4B), two-sided tube reduction or expansion (as shown in FIG. 4C), one-sided chute(as shown in FIG. 4D), or using a stopper 216 (as shown in FIG. 4E and FIG. 4F). The closed chamber 210 is sealed by means of soldering, plasma technology or high frequency welding technology. The stopper 216 includes solder, plastic, metal(such as copper, aluminum, and iron) or nonmetal. Further, the section shape of the stopper is not limited, and the section shape of the stopper can be a circle (as shown in FIG. 4E), an ellipse, a semicircle, a rectangle(as shown in FIG. 4F), a triangle, a trapezoid, an equilateral polygon, or a scalene polygon.

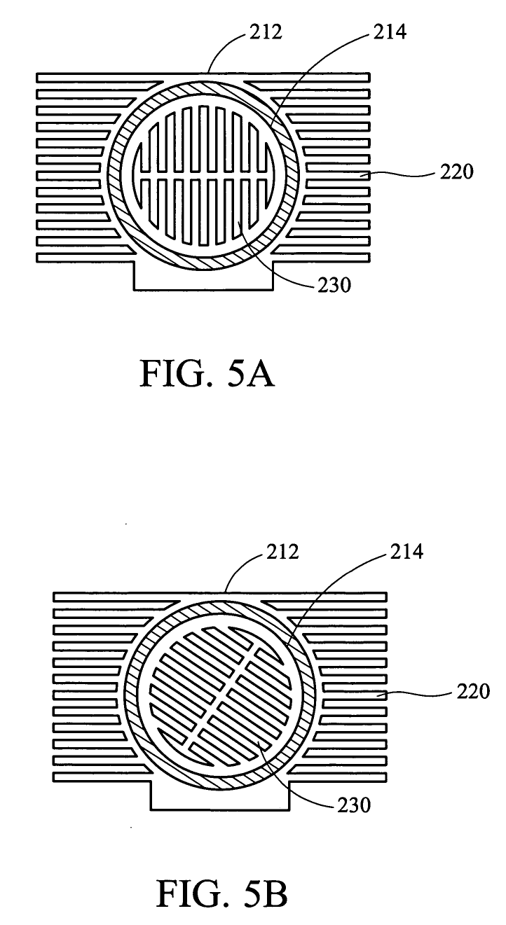

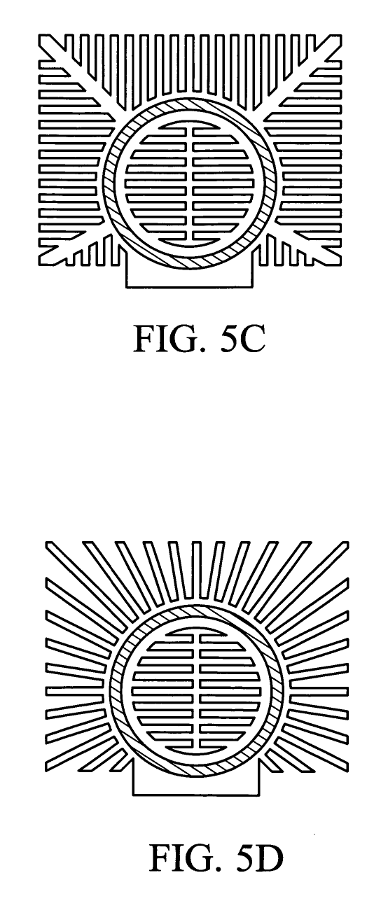

Furthermore, referring to FIG. 5A to FIG. 5D, which show that the conductive structures are disposed in various ways. For example, each of the first heat conductive structure 220 and the second heat conductive 230 includes at least one fin, heat conductive sheet, or other conductive object. The fins or the heat conductive sheet of the first heat conductive structure 220 and the second heat conductive structure 230 are disposed in different manners under different conditions. The arrangement between the first heat conductive structure 220 internally connected to the first annular wall 212 and the second heat conductive structure 230 externally connected to the second annular wall 214 can be the same or different. The individual fins or heat conductive sheets of the heat conductive structure are arranged by intervals horizontally (as shown in FIG. 5A and FIG. 5B), vertically(as shown in FIG. 5A), obliquely (as shown in FIG. 5B), radially(as shown in FIG. 5C and FIG. 5D), or arranged in other ways. Additionally, the first heat conductive structure 220 and the second heat conductive structure 230 may be arranged in the same or different ways.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heat dissipation module, comprising:
a first annular wall;
a second annular wall with respect to the first annular wall, wherein the first annular wall and the second annular wall are jointed to form a closed chamber; and
at least one porous structure disposed on an inner surface of the closed chamber.

2. The heat dissipation module as claimed in claim 1, further comprising:
at least one first heat conductive structure externally connected to the first annular wall; and
at least one second heat conductive structure internally connected to the second annular wall.

3. The heat dissipation module as claimed in claim 1, wherein the first heat conductive structure and the second heat conductive structure are fins or heat conductive sheets.

4. The heat dissipation module as claimed in claim 2, wherein the individual fins or heat conductive sheets of the first heat conductive structure and the second heat conductive structure are arranged by intervals horizontally, vertically, obliquely, radially, or arranged in other ways.

5. The heat dissipation module as claimed in claim 4, wherein the first heat conductive structure and the second heat conductive structure have the same or different arrangements.

6. The heat dissipation module as claimed in claim 1, wherein the first heat conductive structure and the second heat conductive structure are respectively connected to the first annular wall and the second annular wall by means of soldering, locking, engaging, wedging, or gluing.

7. The heat dissipation module as claimed in claim 6, wherein the first heat conductive structure and the second heat conductive structure are respectively engaged with and/or wedged in the first annular wall and the second annular wall by heat mounting.

8. The heat dissipation module as claimed in claim 6, further comprising a bolt, a slide or a self tapping screw for allowing the second conductive structure to be fitted to the second annular wall.

9. The heat dissipation module as claimed in claim 1, further comprising a soldering paste, a grease, or other applicable material capable of acting as a heat conductive interface between the first heat conductive structure and the first annular wall, or between the second heat conductive structure and the second annular wall.

10. The heat dissipation module as claimed in claim 1, wherein the closed chamber is disposed on a base, a shape of which corresponds to a heat source.

11. The heat dissipation module as claimed in claim 10, wherein the base comprises a heat absorbing portion for directly conducting heat from the heat source to the heat dissipation module.

12. The heat dissipation module as claimed in claim 1, wherein the first annular wall and the second annular wall are jointed to form the closed chamber by one-sided tube reduction or expansion, two-sided tube reduction or expansion, one-sided chute, or using a stopper.

13. The heat dissipation module as claimed in claim 12, wherein the stopper has a sectional shape of circle, ellipse, semicircle, rectangle, triangle, trapezoid, regular polygon, or scalene polygon.

14. The heat dissipation module as claimed in claim 11, wherein the closed chamber is formed by soldering, plasma technology or high frequency welding technology.

15. The heat dissipation module as claimed in claim 1, wherein each of the first annular wall and the second annular wall has a sectional shape of circle, ellipse, semicircle, rectangle, triangle, trapezoid, regular polygon, or scalene polygon.

16. The heat dissipation module as claimed in claim 1, wherein the closed chamber comprises a vapor room, and the porous structure contains a working fluid.

17. The heat dissipation module as claimed in claim 16, wherein the working fluid is inorganic compounds, water, alcohol, liquid metal, ketone, CFCs, or organic compounds.

18. The heat dissipation module as claimed in claim 1, wherein the porous structure comprises plastic, metal, compound metal, or nonmetal porous materials.

19. The heat dissipation module as claimed in claim 1, wherein the porous structure comprises a mesh, fiber, sinter, and groove wick.

20. The heat dissipation module as claimed in claim 1, wherein the porous structure is disposed on the inner surface of the closed chamber by sintering, gluing, stuffing, and depositing.
